(19) United States
(12) Patent Application Publication
(10) Pub. No.: US 2008/0293174 A1
(43) Pub. Date: Nov. 27, 2008

(54) Method for forming LED array

(76) Inventors: Ming-Shun Lee, Taipei (TW); Shu-Wei Chiu, Chunan Township (TW); Yea-Chen Lee, Chunan Township (TW)

Correspondence Address: TROXELL LAW OFFICE PLLC, SUITE 1404, 5205 LEESBURG PIKE, FALLS CHURCH, VA, 22041, US

(21) Appl. No.: 12/007,050

(22) Filed: Jan. 4, 2008

(30) Foreign Application Priority Data
Jan. 5, 2007 (TW) 096100469

(51) Int. Cl. H01L 21/00

(52) U.S. Cl. 438/29

(57) ABSTRACT

A method for forming LED array is disclosed herein. First, a LED wafer, a substrate having a LED epitaxial layer thereon, is cut into a plurality of LED sticks. Then, each space layer is bonded between every two LED sticks to form a LED array.

### BACKGROUND OF THE INVENTION

(a) Field of the Invention

The invention is related to a method for forming light emitting diodes (LED), especially to a LED array forming method, in which the LED substrate is cut into LED sticks and each space layer is bonded between every two LED sticks to form a LED array.

(b) Description of the Prior Art

In recent years, as the light emitting efficiency of LED is enhanced continuously, there is a trend for the LED to replace the conventional florescent lamps and light bulbs, and the manufacture trends of LED are also heading to develop high power and large area models. However, as the defect density is not reduced, along with the increase of LED area, the yield rate is dropping down.

Due to the poor yield rate in the conventional large area LEDs as the defect density is not reduced, it is necessary to propose a forming method for the LED array in order to replace the conventional large area LED devices, and to resolve the poor yield rate problems in the large area LED.

### SUMMARY OF THE INVENTION

The purpose of the invention is to provide a method for forming LED array, in which a LED wafer is cut to a plurality of LED sticks while each space layer is bonded between every two LED sticks, thereby to form a LED array.

The second purpose of the invention is that same color lights of LED sticks in one of the red, blue or green lights are used to form a monochrome LED array and the LED sticks of red, blue and green lights are lined up to form a white light LED array.

Another purpose of the invention is that a LED array with electrodes is formed by bonding the electrode of each LED stick with a metal bar.

Based on above purposes, the invention provides a method for forming LED array, first the wafer has a substrate which includes a LED epitaxial layer, whereof the LED wafer is cut to a plurality of LED sticks, and each space layer is bonded in between every two LED sticks, thereby to form a LED array.

### BRIEF DESCRIPTION OF THE DRAWINGS

FIGS. 1A˜1C are embodying example schematic diagrams of the invention showing the forming method for LED arrays.

FIGS. 2A˜B are embodying example schematic diagrams of the invention showing the electrode junction method for LED arrays.

FIG. 3A˜3C are another embodying example schematic diagrams of the invention showing the forming method for LED sticks.

### DETAILED DESCRIPTION OF THE PREFERRED EMBODIMENTS

Detail embodiments of the invention are described in the herein, whereof besides the ones described, the invention can also be widely applied in other embodied examples. Therefore, the range of the invention shall be covered by the claims but not be limited to the proposed embodied examples only.

Further, in order to provide a more clearer description for easier understanding the invention, the items shown in the figures are not correspondingly dimensioned, whereof some of the sizes and relevant dimensions may be exaggerated and irreverent details are not shown to maintain the neatness of the figures.

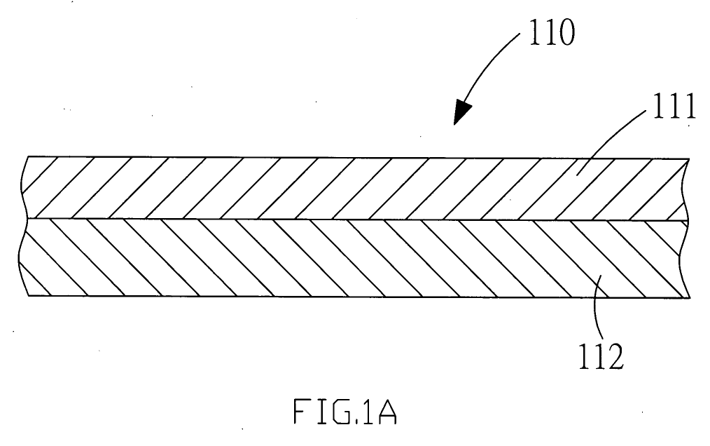

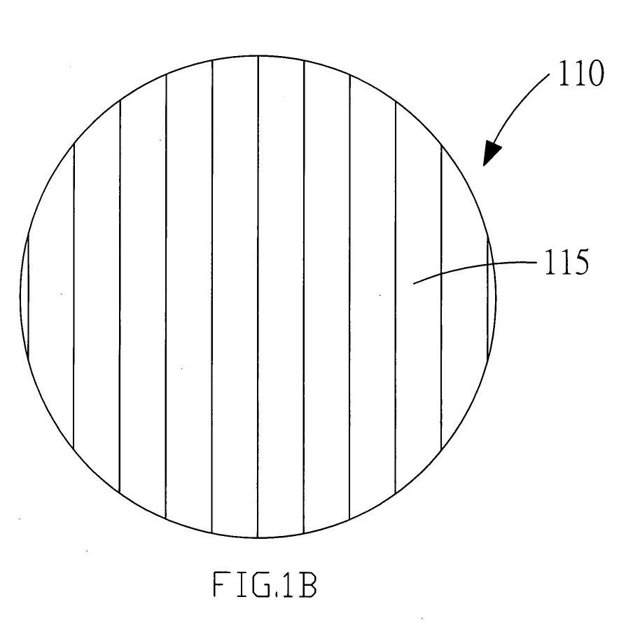

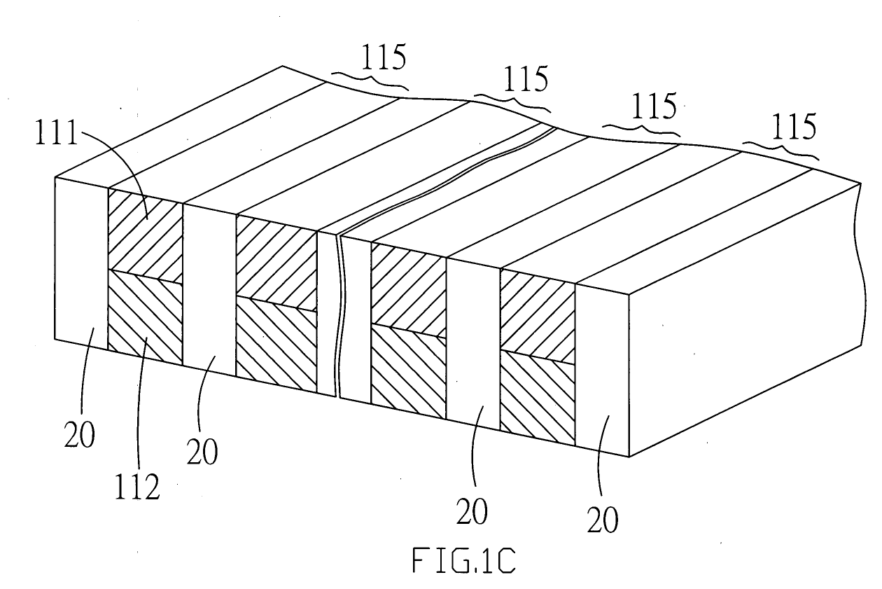

FIGS. 1A to 1B are embodying example schematic diagrams of the invention showing the forming method for LED arrays.

A plurality of LED sticks shall be provided first: i.e as shown in FIG. 1A, the LED wafer 110 has a substrate 112 and a LED epitaxial layer 111, the substrate 112 can be one of the conducting or non-conducting substrates, whereof the LED epitaxial layer 111 is comprised of a type I semi-conductor layer, an active layer and a type II semi-conductor layer which is contrary to the type I one. The LED wafer 110 is cut to a plurality of LED sticks 115 as shown in FIG. 1B.

Secondly, as shown in FIG. 1C, each space layer 20 is bonded in between every two LED stickers 115, and the bonding method such as glue bonding can be used, whereof the material of the space layer 20 can be semi-conductor material such as silicon or ceramic material. Further, both sides of the space layer 20 can be high reflection treated to form the high reflective layers (not shown in the figures) before it is bonded with the LED stick, whereof the high reflective layer can be a high reflective metal layer or multiple layers of high reflective coating, and the material of the high reflective metal layer can be gold, aluminum, silver or one of their alloys, thereby to make the LED emitting light to the same direction and increase the directivity of the LED.

To form a monochrome light LED array, the LED stick must be of the same color lights, whereof the light of LED stick can be one of the red, blue or green lights, etc. If a white light LED array is requested, the LED sticks of red, blue and green lights are lined up in order to form a white light LED array.

Then, the LED array is cut in proper lengths to form the LED devices 100.

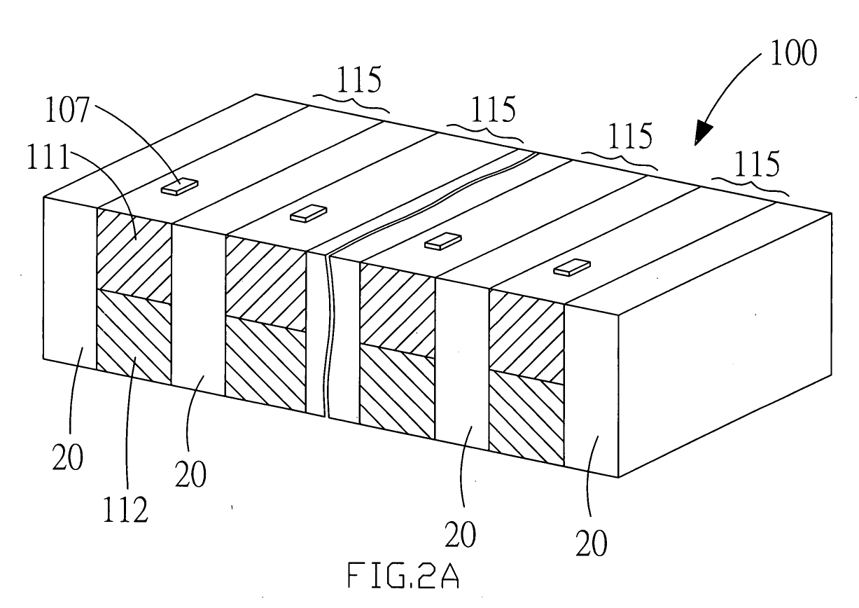

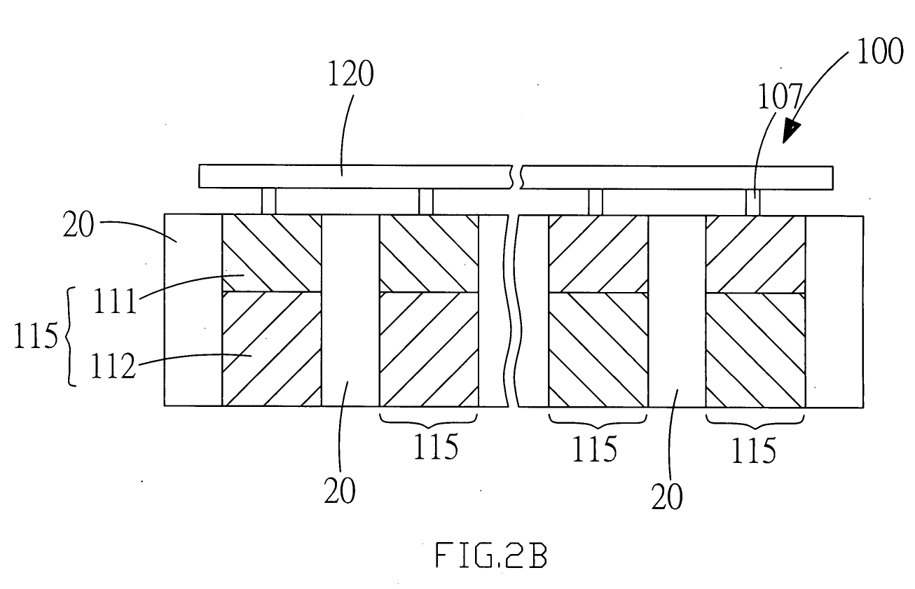

FIGS. 2A˜2B are embodying example schematic diagrams of the invention showing the electrode junction method for LED arrays. The LED Device 100 manufactured by the aforesaid method as shown in FIG. 2A, in which the LED stick 115 has a substrate 112 which includes a LED epitaxial layer 111 and an electrode 107, whereby the metal bar 120 is bonded with the electrode 107 of each LED stick 115 as shown in figure B (side view) without the needs to be individually bonded by wires.

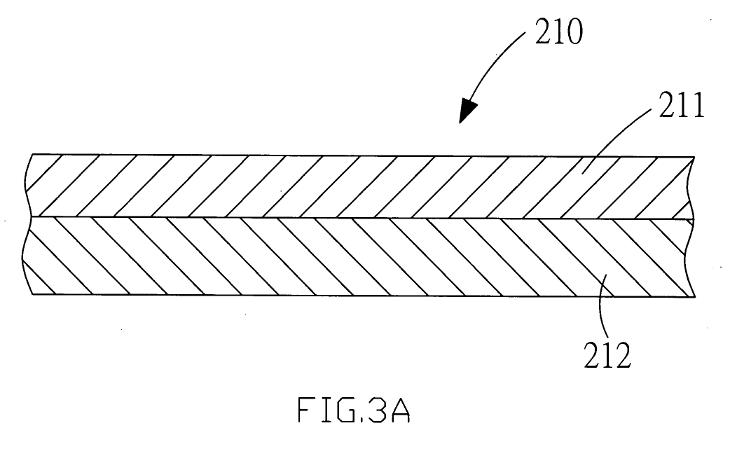

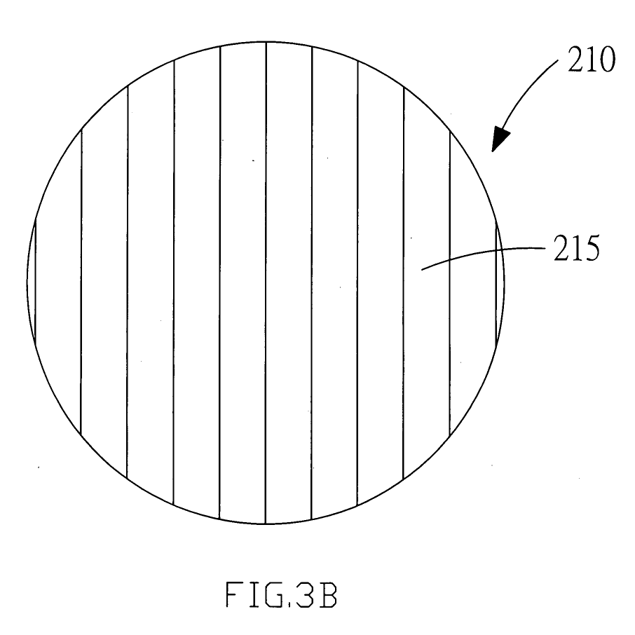

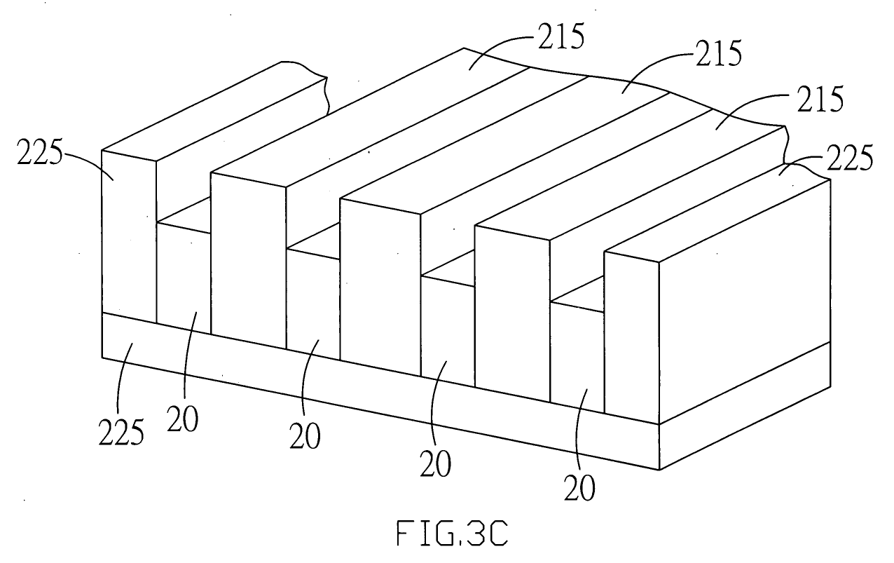

FIG. 3A˜3C are another embodying example schematic diagrams of the invention showing the forming method for LED sticks. As shown in FIG. 3A, A LED wafer 210 has a substrate 212 which includes a LED epitaxial layer 211, whereof the LED epitaxial layer 111 includes a type I semi-conductor layer, an active layer and a type II semi-conductor layer which is contrary to the type I, whereof the substrate 212 can be a non-conductive or a conductive substrate.

After that, as shown in FIG. 3B, the LED wafer 210 is cut to a plurality of LED sticks 215, and as shown in FIG. 3C, a plurality of space layers 20 are provided in-between every two LED sticks 215, whereof the height of the space layer 20 shall be lower than the height of the LED stick 215, whereof material of the space layer 20 can be semi-conductor material such as silicon or ceramic material. Secondly, the row of LED sticks 215 and space layers 20 are fixed by the fixtures 225, then the surface and exposed side of the LED sticks 215 are further processed.

The exposed sides and surfaces of the LED sticks can be anti-reflection treated to enhance light emitting efficiency, whereof the anti-reflection treatment includes roughening treatment and anti-reflection coating), so that total reflection of emitting lights of the LED sticks can be avoided and the light emitting efficiency can be enhanced to achieve the high efficient LED sticks (not shown in the figure). Through the said method, the exposed sides of the LED sticks can be high reflection treated to form high reflective layers so that the LED sticks can emit lights at the same direction, and its light directivity can be increased, whereby to achieve the high directive LED sticks (not shown in the figures). Whereof, the high reflective layer is a high reflective metal layer or multiple layers of high reflective coating, when the high reflective layer is a high reflective metal layer, a transparent dielectric layer is formed between the high reflective metal layer and the LED epitaxial layer to avoid short-circuit between the high reflective layer and LED epitaxial layer. The LED sticks are bonded to a LED array which is cut in proper lengths to become LED devices.

As the LED arrays formed by this method are not directly cut into large area LED devices, the yield rate can be increased. Besides, this method can form monochrome LED arrays, and white light LED arrays by matching with red, blue and green lights LED sticks. Through anti-reflection treatment on the surface and exposed sides of the LED sticks, the complete light reflection of the LED device can be avoided, and the light emitting efficiency of the formed LED array is also enhanced. Through high-reflection treatment on the sides of the LED sticks, the light of the LED stick is reflected by the high reflective layer to emit lights at the same direction, thereby to increase the directivity of the light as well as the directivities of the formed LED arrays.

The aforesaid embodiments only described the technical thought and characteristics of the invention. Its main purpose is make people who is familiar with this art to understand the content of the invention and to carry out accordingly, therefore they shall not be used to limit the range of the claims in the application, i.e all equivalent variations or modifications related to the spirit of the invention shall still be included within the scope of the claims.

1. A method for forming LED array, whereof it includes the following steps:
A plurality of LED sticks are provided; and
Each space layer is bonded in-between every two LED sticks to form the said LED array.

2. A method for forming LED array as in claim 1, whereof the said plurality of LED sticks are cut from a LED wafer, whereof the said LED wafer has a substrate which includes a LED epitaxial layer 211, whereof the LED epitaxial layer is comprised of a type I semi-conductor layer, an active layer and a type II semi-conductor layer which is contrary to type I.

3. The method for forming LED array as in claim 2, whereof the substrate can be one of the conductive or non-conductive substrates.

4. The method for forming LED array as in claim 1, whereof the kind of the plurality of LED sticks are one of the red, blue or green lights, whereby to make a said LED array of monochrome color light.

5. The method for forming LED array as in claim 1, whereof in the bonding process for several LED sticks, the LED sticks of red, blue and green lights are lined up in order to form a white light LED array

6. The method for forming LED array as in claim 1, whereof the two sides of the said space layer have high reflective layers which are high reflection treated.

7. The method for forming LED array as in claim 1, whereof the epitaxial layer of each LED stick is further provided with an electrode to be bonded with a metal bar.

8. A method for forming LED array to enhance its light emitting efficiency, whereof it includes the following steps:
A plurality of LED sticks, whereof the surface and both sides of each said LED sticks are anti-reflection treated; and
Each space layer is bonded in between every two said LED sticks to form the said LED array.

9. The method for forming LED array as in claim 8, whereof the method for forming the said LED stick includes the following steps:
A LED wafer is cut to a plurality of LED sticks, the said LED wafer has a substrate which includes a LED epitaxial layer;
The said plurality of LED sticks are fixed by fixtures, one space layer is between every two LED sticks, whereof the height of the said space layer shall be lower than the said LED sticks; and
The surfaces and exposed sides of the said plurality of LED sticks are anti-reflection treated.

10. The method for forming LED array as in claim 9, whereof the LED epitaxial layer includes a type I semi-conductor layer, an active layer and a type II semi-conductor layer which is contrary to type I.

11. The method for forming LED array as in claim 9, whereof the said anti-reflection treatment is one of the surface roughening treatment or anti-reflection coating.

12. A method for forming LED array to increase the light directivity of the said LED array, whereof it includes the following steps:
A plurality of LED sticks, whereof two sides of the said LED sticks are high reflection treated to form high reflective layers; and
Each space layer is bonded in-between every two LED sticks to form the said LED array.

13. The method for forming LED array as in claim 12, whereof the high reflective layer is a high reflective metal layer.

14. The method for forming LED array as in claim 13, whereof a transparent dielectric layer is between the high reflective layer and the said LED stick to avoid short-circuit between the high reflective layer and the said LED stick.

15. The method for forming LED array as in claim 12, whereof the high reflective layer is a multiple-layers high reflective coating.
